(19) United States
(12) Patent Application Publication
(10) Pub. No.: US 2026/0216919 A1
(43) Pub. Date: Jul. 30, 2026

(54) CUTTING APPARATUS, CUTTING METHOD, AND METHOD FOR MANUFACTURING CUT PRODUCT

(71) Applicant: TOWA CORPORATION, Kyoto (JP)

(72) Inventors: Hajime WATANABE, Kyoto-shi, Kyoto (JP); Kanji ISHIBASHI, Kyoto-shi, Kyoto (JP); Shoichi KATAOKA, Kyoto (JP); Rin SAKAMOTO, Kyoto (JP); Kyotaro HORIMOTO, Kyoto (JP)

(73) Assignee: TOWA CORPORATION, Kyoto (JP)

(21) Appl. No.: 19/145,492

(22) PCT Filed: Nov. 28, 2023
(86) PCT No.: PCT/JP2023/042457

§ 371 Date: Jul. 2, 2025

(30) Foreign Application Priority Data
Mar. 2, 2023 (JP) 2023-032281

(51) Int. Cl. B28D 5/00; B28D 5/02; H10W 70/05

(52) U.S. Cl. CPC B28D 5/0064; B28D 5/0082; H10W 70/096; B28D 5/022

(57) ABSTRACT

Provided are a cutting apparatus, a cutting method, and a method for manufacturing a cut product, with which it is possible to perform accurate half cutting with little variability. The cutting apparatus according to the present invention comprises a table for holding an object to be cut, a cutting mechanism having a blade capable of cutting the object to be cut, a detecting part for detecting contact between the blade and an upper surface of the object to be cut, and a control part for controlling the cutting mechanism, wherein the control part controls a height-direction position of the blade when cutting the object to be cut on the basis of a height position of the blade when the detecting part detects contact between the blade and the upper surface of the object to be cut.

### TECHNICAL FIELD

The present invention relates to a cutting apparatus, a cutting method, and a method for manufacturing a cut product.

### BACKGROUND TECHNOLOGY

Patent Literature 1 discloses a method for manufacturing a package chip. In this manufacturing method, a package substrate is cut along a division planned line with a first cutting blade to form a half cutting groove (half cutting step). Subsequently, after a step of performing plating treatment on electrodes of the package substrate, a step of full cutting is executed. Thus, the package substrate is singulated, and semiconductor packages are produced.

### RELATED ART LITERATURE

### Patent Literature

Patent Literature 1: Japanese Patent Application Laid-Open No. 2020-161615

### SUMMARY OF INVENTION

### Problem to be Solved by the Invention

Meanwhile, in recent years, more precise semiconductor packages have been demanded, and accordingly, for example, there have been requirements for accurate half cutting with little variability. Such a problem is not limited to cutting of a package substrate, but is a problem that can occur in all products to be cut by half cutting. The present invention has been made to solve such a problem, and provides a cutting apparatus, a cutting method, and a method for manufacturing a cut product that make it possible to perform accurate half cutting with little variability.

### Means for Solving the Problem

A cutting apparatus according to the present invention includes a table holding an object to be cut; a cutting mechanism having a blade capable of cutting the object to be cut; a detecting part detecting contact between the blade and an upper surface of the object to be cut; and a control part controlling the cutting mechanism, in which the control part controls a position of the blade in a height direction during cutting of the object to be cut based on a height position of the blade when the detecting part detects contact between the blade and the upper surface of the object to be cut.

A cutting method according to the present invention includes a step of holding an object to be cut on a table; a step of detecting a height position of a blade by bringing the blade capable of cutting the object to be cut into contact with an upper surface of the object to be cut; and a step of controlling a position of the blade in a height direction during cutting of the object to be cut based on the height position of the blade detected.

A method for manufacturing a cut product according to the present invention includes a step of performing half cutting on the object to be cut by the above-mentioned cutting method; and a step of separating the object to be cut by performing full cutting on a half cutting groove formed by the half cutting.

### Effects of the Invention

According to the present invention, it is possible to achieve accurate half cutting with little variability.

### BRIEF DESCRIPTION OF THE DRAWINGS

FIG. 1A is a plan view of an example of a package substrate.

FIG. 1B is a cross-sectional view of FIG. 1A.

FIG. 2 is a perspective view of an example of a semiconductor package.

FIG. 3 is a plan view of a cutting apparatus according to an embodiment of the present invention.

FIG. 4 is a side view of FIG. 3.

FIG. 5 is a block diagram showing an electrical configuration of the cutting apparatus.

FIG. 6 is an enlarged cross-sectional view of a holding unit.

FIG. 7 is an enlarged cross-sectional view of the holding unit with a package substrate arranged thereon.

FIG. 8A is a plan schematic view of the vicinity of a half cutting groove.

FIG. 8B is a side schematic view of the vicinity of the half cutting groove.

FIG. 9A is a cross-sectional view showing the procedure for cutting a package substrate.

FIG. 9B is a cross-sectional view showing the procedure for cutting the package substrate.

FIG. 9C is a cross-sectional view showing the procedure for cutting the package substrate.

FIG. 10 is a flowchart showing the procedure for half cutting of a package substrate.

FIG. 11 is a cross-sectional view showing the relationship between a package substrate and a recess in the second embodiment.

FIG. 12 is a schematic view showing the relationship between a pressing mechanism and a blade from a side in the second embodiment.

FIG. 13 is a plan view schematically showing the pressing mechanism of FIG. 11.

FIG. 14 is a schematic view showing the relationship between the pressing mechanism and the blade of FIG. 12 from the front.

FIG. 15A is a cross-sectional view showing a package substrate pressed by the pressing mechanism.

FIG. 15B is a cross-sectional view showing a package substrate pressed by the pressing mechanism.

FIG. 16A is a plan view showing an example of a measurement location for the height position of the front of a package substrate.

FIG. 16B is a plan view showing an example of measurement locations for the height position of the front of a package substrate.

FIG. 16C is a plan view showing an example of measurement locations for the height position of the front of a package substrate.

FIG. 17 is a view illustrating another method of height detection performed by the detecting part.

### DESCRIPTION OF THE EMBODIMENTS

Hereinafter, a cutting apparatus according to an embodiment of the present invention will be described in detail with reference to the figures. In the figures, identical or equivalent parts are denoted by the same reference numerals, and the description thereof will not be repeated. In addition, each figure is schematically depicted with subjects appropriately omitted or exaggerated for ease of understanding. Besides, for convenience, the description will be based on the directions shown in several figures, but the present invention is not limited to being configured in these directions.

### A. First Embodiment

The cutting apparatus according to this embodiment produces multiple semiconductor packages as cut products by cutting a package substrate, which is an example of an object to be cut. Here, the concept of the term “cutting” includes separating the object to be cut into multiple singulated cut products, and removing a part of the object to be cut. Hereinafter, cutting that separates the object to be cut into multiple singulated cut products may be referred to as full cutting, and cutting that does not separate the object to be cut but removes a part thereof in the thickness direction may be referred to as half cutting. In the following, the package substrate, which is the target to be cut, will be described first, followed by a description of the cutting apparatus that cuts the package substrate.

### 1. Package Substrate

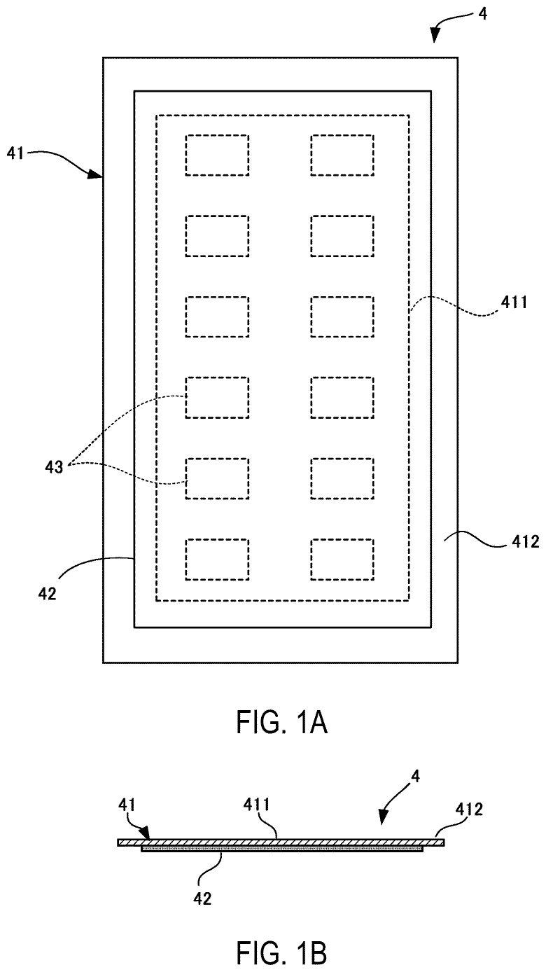

FIG. 1A is a plan view of a package substrate 4, and FIG. 1B is a cross-sectional view of FIG. 1A. The type of the package substrate 4 serving as the target in this embodiment is not particularly limited. The package substrate 4 is, for example, a wettable flank QFN (Quad Flat Non-leaded) package substrate. As shown in FIG. 1A and FIG. 1B, this package substrate 4 includes a rectangular substrate 41 made of metal such as copper plate, and a rectangular resin layer 42 that resin-seals one surface of the substrate 41. Hereinafter, one surface of the substrate 41 on which the resin layer 42 is formed is referred to as a first surface, and the opposite surface to the first surface is referred to as a second surface. A lead frame or a printed wiring board can be used as the substrate 41, and in this embodiment, the substrate 41 is configured with a lead frame as an example.

On the first surface of the lead frame (substrate 41) in this embodiment, semiconductor chip mounting parts (die pads, not shown) are arranged in a matrix shape, and electronic elements 43 such as semiconductor chips, resistor elements, and capacitor elements are fixed to the semiconductor chip mounting parts. The lead frame is made of metal such as copper (Cu) or 42 alloy (Fe—Ni), and has conductivity. A lead-free metal plating layer or a lead-free solder plating layer (not shown) is often formed in advance on the surface of the lead frame. Numerous leads that serve as terminals for connection to the outside are arranged around each die pad. These numerous leads are each connected to tie bars, which are metal frames arranged in a grid pattern in the lead frame. In addition, multiple electrodes (not shown) provided on each electronic element 43 are electrically connected to the respective leads arranged around the die pad via bonding wires made of gold wires or copper wires.

The substrate 41 in this embodiment is configured with a rectangular use region 411 and a non-use region 412 surrounding the use region 411. The non-use region 412 is a region that includes the outer edge of the substrate 41, which is not used as a product and will be removed later. On the other hand, the use region 411 is a region to be used as a product, and is a region including the die pads, leads, and tie bars of the lead frame mentioned above. The resin layer 42 is molded in a rectangular shape to cover the use region 411 of the substrate 41 and a part of the non-use region 412 outside the use region 411. That is, the electronic elements 43 and bonding wires arranged in the use region 411 are sealed by the resin layer 42. With such a resin layer 42 being formed, a step corresponding to the thickness of the resin layer 42 is formed between the first surface of the substrate 41 and an end surface of the resin layer 42 (the lower surface in FIG. 1B).

In addition to the example described above, a semiconductor substrate, a metal substrate, a ceramic substrate, a glass substrate, a resin substrate, etc. can be used as the substrate 41 constituting the package substrate 4. In a case where the substrate is not made of metal and does not have conductivity, the portion of the substrate that is in contact with a frame part 212a of a support part 212 to be described later (the outer peripheral part to be described later) may be configured to have conductivity. Also, the substrate 41 constituting the package substrate 4 may or may not have wirings applied thereto.

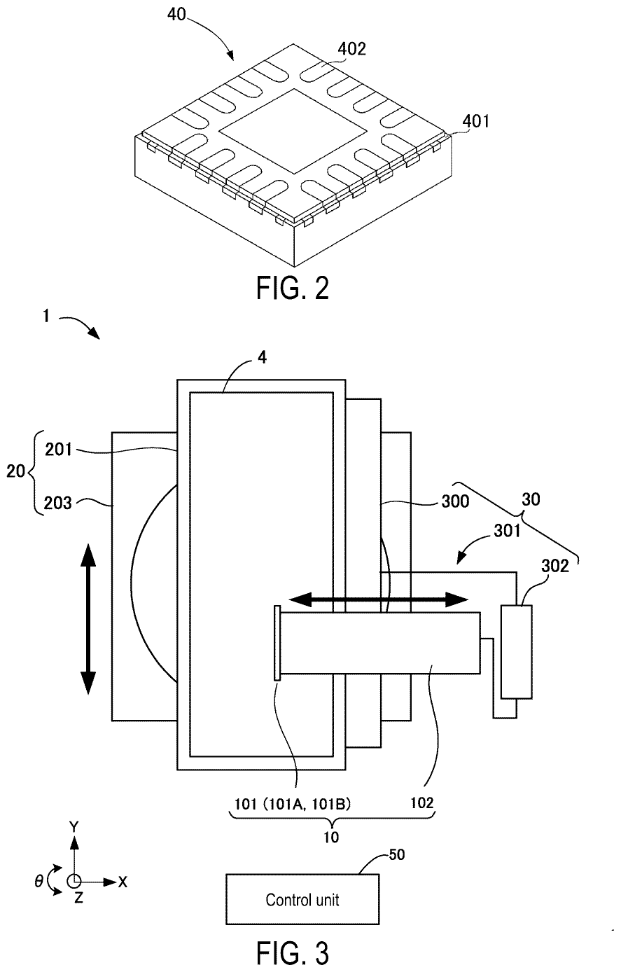

FIG. 2 is a perspective view of a semiconductor package. By performing half cutting and full cutting on the package substrate 4 shown in FIG. 1A and FIG. 1B, a semiconductor package 40 as shown in FIG. 2 is manufactured.

As shown in FIG. 2, in the semiconductor package 40, a step part 401 is formed at the boundary portion between the upper surface (the surface where terminals 402 are formed) and the side surface. In a case where the semiconductor package 40 is surface-mounted, solder enters the step part 401. This realizes a fillet-shaped solder connection structure for the semiconductor package 40, which can secure the connection. Also, since the solder enters the step part 401 and forms a fillet shape, the connection state of the solder can be easily observed from the side surface of the semiconductor package 40 in the visual inspection after mounting. Thus, the semiconductor package 40 has various advantages. A method for forming the step part 401 will be described later.

### 2. Overview of Cutting Apparatus

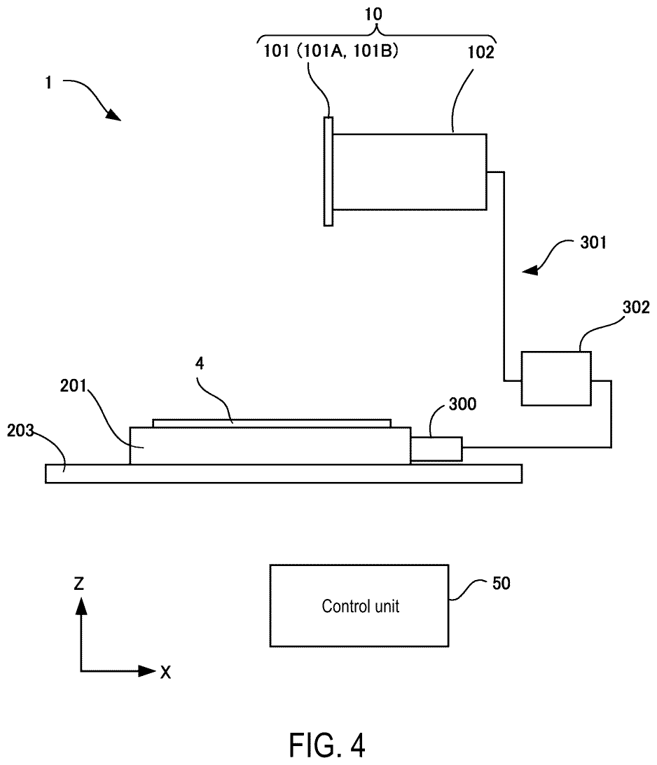

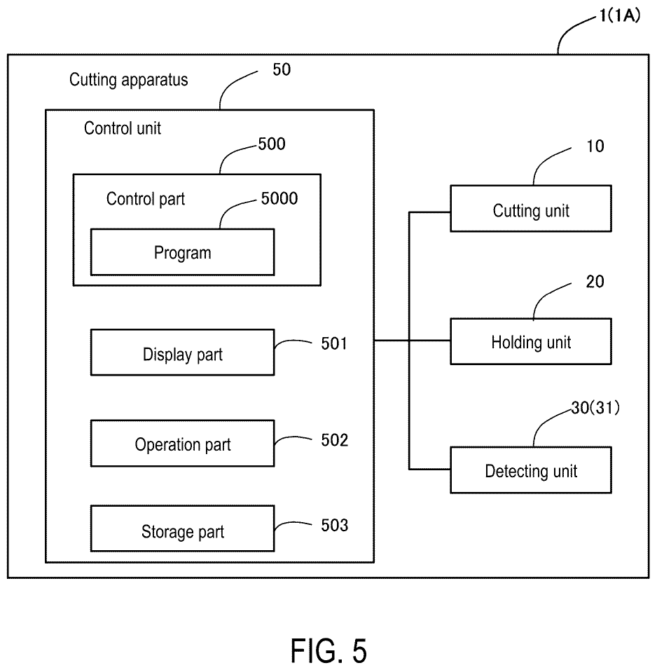

FIG. 3 is a plan view of a cutting apparatus 1 according to this embodiment, FIG. 4 is a side view of FIG. 3, and FIG. 5 is a block diagram showing an electrical configuration of the cutting apparatus 1.

As shown in FIG. 3 to FIG. 5, this cutting apparatus 1 mainly includes a cutting unit (cutting mechanism) 10, a holding unit 20, a detecting unit 30, and a control unit (control part) 50. That is, in this cutting apparatus 1, the package substrate 4 held by the holding unit 20 is cut by the cutting unit 10. At this time, the height for cutting the package substrate 4 is detected by the detecting unit 30. In addition, a series of cutting processes is controlled by the control unit 50.

It goes without saying that the cutting apparatus 1 may include units other than those described above. For example, the cutting apparatus 1 may include a substrate supply unit that supplies the package substrate 4, an inspection unit that inspects the package substrate 4 and/or the semiconductor package 40, a cleaning unit that cleans and/or dries the cut semiconductor package 40, a transport unit that transports the cut semiconductor package 40 to a storage part, etc. In the following, the configurations of the cutting unit 10, the holding unit 20, the detecting unit 30, and the control unit 50 will be described in detail.

### <2-1. Cutting Unit>

As shown in FIG. 3 and FIG. 4, the cutting unit 10 is arranged above the holding unit 20 and is configured to cut the package substrate 4. The cutting unit 10 includes a blade 101, a spindle part 102, and a movement mechanism (not shown) that moves the spindle part 102 to a desired position within the cutting apparatus 1. The cutting apparatus 1 may have a twin spindle configuration including a pair of spindle parts 102, or may have a single spindle configuration including only one spindle part 102. The spindle part 102 extends in the X-axis direction and moves along the X-axis and Z-axis in FIG. 3 and FIG. 4 by the movement mechanism (not shown). The operation of the movement mechanism, that is, the movement of the spindle part 102 and the position in the X-axis and Z-axis directions, is controlled by the control unit 50 to be described later. In the following, the Z-axis direction in FIG. 3 and FIG. 4 may be referred to as the height direction of the spindle part 102 or the blade 101.

The blade 101 is a ring-shaped blade, and is detachably attached to the tip part of the spindle part 102 and rotates around the X-axis. In other words, the blade 101 moves along the X-axis and Z-axis in FIG. 3 and FIG. 4 together with the spindle part 102.

The blade 101 attached to the spindle part 102 is configured to perform half cutting and full cutting on the package substrate 4 by rotating at high speed as rotation is transmitted from the spindle part 102. In the following, the blade for half cutting is referred to as a first blade 101A, and the blade for full cutting is referred to as a second blade 101B. The first blade 101A has a first thickness, and the second blade 101B has a second thickness smaller than the first thickness. In other words, the thickness of the second blade 101B is thinner than the thickness of the first blade 101A. A blade that corresponds to either one of the first blade 101A and the second blade 101B is simply referred to as the blade 101. In this embodiment, either one of the first blade 101A and the second blade 101B is attached to the spindle part 102 to perform cutting.

The first blade 101A is composed of a material having conductivity, and in a state of being attached to the spindle part 102, the first blade 101A is in conduction with the spindle part 102. The spindle part 102 is electrically connected to a detection circuit 301 to be described later.

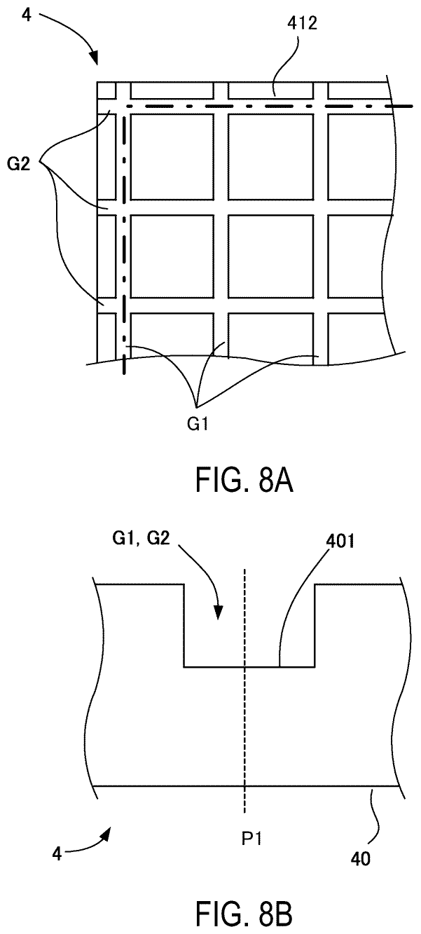

In a case of performing half cutting on the package substrate 4, the package substrate 4 is cut by moving the first blade 101A relative to a table 201 to be described later. Specifically, a part of the package substrate 4 is removed in the thickness direction. By performing half cutting along the longitudinal direction and the lateral direction on the package substrate 4, a half cutting groove G1 extending in the longitudinal direction of the package substrate 4 and a half cutting groove G2 extending in the lateral direction of the package substrate 4 are formed (see FIG. 8A). On the other hand, in a case of performing full cutting on the package substrate 4, the package substrate 4 is cut along a groove pattern by moving the second blade 101B relative to the table 201. This cuts and separates the portions of the half cutting grooves G1 and G2, and the package substrate 4 is singulated into multiple separated semiconductor packages 40 (see FIG. 2).

### <2-2. Holding Unit>

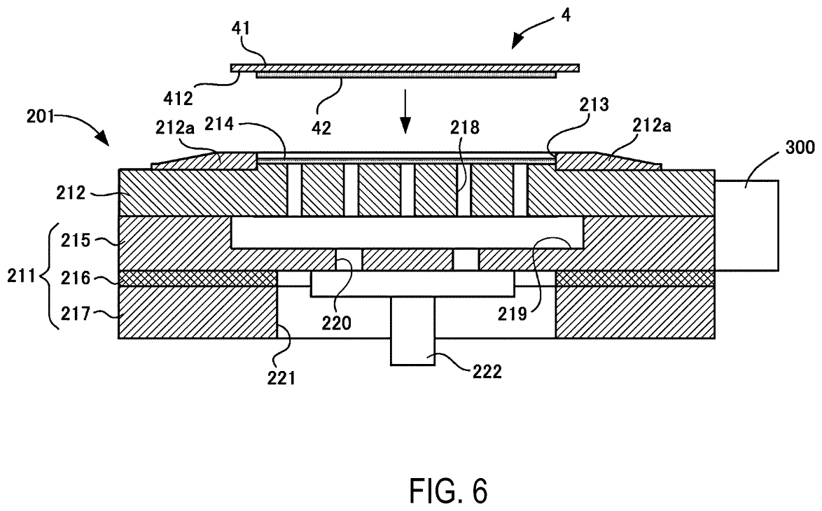

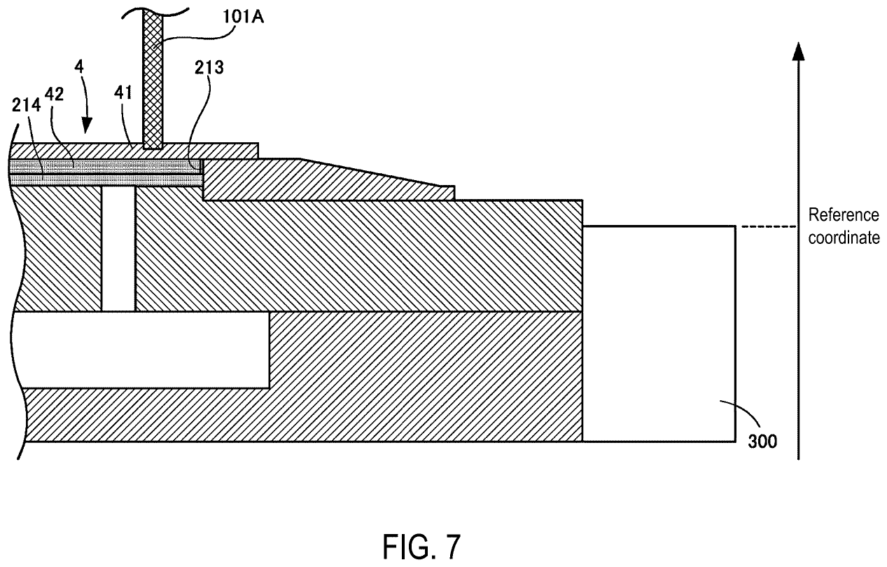

FIG. 6 is an enlarged cross-sectional view of the holding unit, and FIG. 7 is an enlarged cross-sectional view of the holding unit with the package substrate arranged thereon. In the following, the holding unit 20 will be described with reference to these figures as well. First, as shown in FIG. 3 and FIG. 4, the holding unit 20 includes a movement mechanism 203 and a table 201, and the package substrate 4 is held on the table 201. The cutting apparatus 1 may have a twin cut table configuration with two holding units 20, or may have one holding unit 20, or may have three or more holding units 20. The package substrate 4 is held by the holding unit 20 and is cut along the longitudinal direction and the lateral direction thereof while moving relative to the blade 101.

As shown in FIG. 6, the table 201 has a base 211 and a conductive support part 212 arranged on the base 211, and the package substrate 4 is arranged on the support part 212. The base 211 and the support part 212 are fixed, for example, with bolts or the like. The support part 212 has an annular frame part 212a, and a rectangular recess 213 is formed on the upper surface of the support part 212 by this frame part 212a. A plate-shaped suction plate 214 is arranged in this recess 213. The suction plate 214 in this embodiment can be configured with a resin film provided at least on the suction surface side that sucks the package substrate 4. The thickness of the suction plate 214 is smaller than the depth of the recess 213, and a space (hereinafter referred to as an arrangement space) is formed in the recess 213 above the upper surface of the suction plate 214. The planar shape of the recess 213 is approximately the same as or slightly larger than the rectangular shape of the resin layer 42 of the package substrate 4. The depth of the arrangement space of the recess 213 (the depth from the upper surface of the suction plate 214 to the frame part 212a) is approximately the same size as or slightly larger than the thickness of the resin layer 42. Thus, the recess 213 is formed to approximately accommodate the resin layer 42 (see FIG. 7). In this embodiment, the frame part 212a is a separate body from the support body 212 and is fixed and integrated, for example, with bolts or the like, but the frame part 212a may not be a separate body from the support body 212. In a case where the frame part 212a is a separate body from the support body 212, by replacing only the frame part 212a, it is possible to cope with various types of package substrates 4 with different sizes, substrate thicknesses, and resin layer thicknesses. In addition, the replacement portion can be made smaller, which also improves workability during replacement.

As shown in FIG. 7, when the resin layer 42 is arranged in the recess 213, the non-use region 412 in the portion of the substrate 41 where the resin layer 42 is not formed is in contact with the upper surface of the support part 212 outside the recess 213. Here, the portion in contact with the support part 212 when the package substrate 4 is arranged on the table 201 may be referred to as the “outer peripheral part” of the package substrate 4. As described above, since the support part 212 is made of a conductive material such as stainless steel, when the outer peripheral part of the package substrate 4 in this embodiment is arranged, the support part 212 and the package substrate 4 are in conduction. As described above, the upper surface of the support part 212 (the upper surface of the conduction part) where the non-use region 412 of the package substrate 4 is arranged is positioned above the upper surface of the suction plate 214. That is, the upper surface of the support part 212 (conduction part) in contact with the non-use region 412 in the portion of the package substrate 41 where the resin layer 42 is not formed is positioned above the upper surface of the suction plate 214, which is the surface in contact with the resin layer 42.

Multiple air passages 218 that penetrate the support part 212 in the vertical direction are formed on the lower surface of the recess 213. The upper end of each air passage 218 leads to a through hole (not shown) formed in the suction plate 214.

The base 211 has a first portion 215 in contact with the lower surface of the support part 212, and a second portion 217 that is fixed to the lower surface of the first portion 215 via an insulating layer 216. The first portion 215 and the second portion 217 are, for example, made of a conductive material such as stainless steel. A space 219 that communicates with multiple air passages 218 of the support part 212 is formed in the first portion 215, and an air passage 220 that opens on the lower surface of the first portion 215 extends from this space 219.

A through hole 221 is formed in the second portion 217 in a portion corresponding to the air passage 220 of the first portion 215, and a pipe 222 connecting the air passage 220 and a pump (not shown) is provided in this through hole 221. Therefore, by driving the pump, air is sucked from the through hole of the suction plate 214. This causes the resin layer 42 to be sucked to the suction plate 214, and the package substrate 4 is held on the support part 212. Even in a case where the thickness of the resin layer 42 is thinner than expected and the resin layer 42 does not come into contact with the upper surface of the suction plate 202 when the package substrate 4 is arranged on the support part 212, the air in the recess 213 closed by the package substrate 4 is sucked, thereby creating negative pressure inside the recess 212, and the substrate 41 is sucked downward, and the resin layer 42 is held in contact with the suction plate 214. The holding unit 20 does not necessarily include the suction plate 214, and may be configured without the suction plate 214, or may include another member instead of the suction plate 214. Also, multiple pipes 222 connected to the pump may be provided where the through hole 221 is formed.

As shown in FIG. 3, the table 201 is rotatable in the direction θ in the figure on the movement mechanism 203. That is, the table 201 is rotatable on the horizontal plane and is movable along the Y-axis in the figure by the movement mechanism 203. The operations of the table 201 and the movement mechanism 203 are controlled by the control unit 50 to be described later.

### <2-3. Detecting Unit>

The detecting unit 30 is used for detecting the position in the height direction (Z-axis direction) of the spindle part 102 and the first blade 101A. As shown in FIG. 3 and FIG. 4, the detecting unit 30, which is an example of the detecting part of the present invention, includes a CCS (Contact Cutter Setup) block 300, a detection circuit 301, and a detection device 302. The CCS block 300 is attached to a side of the table 201 and is capable of moving together with the table 201. In addition, the CCS block 300 has conductivity and is in conduction with the support part 212 described above. Therefore, when the package substrate 4 is arranged on the support part 212, the package substrate 4 and the CCS block 300 are in conduction.

The detection circuit 301 is a circuit configured to conduct electricity via the first blade 101A and the CCS block 300 when the first blade 101A comes into contact with the upper surface of the CCS block 300, and is electrically connected to the CCS block 300 and the spindle part 102, with the detection device 302 incorporated into the detection circuit 301. In addition, since both the support part 212 and the first portion 215 have conductivity and are in contact with the CCS block 300 (see FIG. 6), the detection circuit 301 functions similarly in a case where the first blade 101A comes into contact with a portion of the package substrate 4 that has conductivity.

The detection circuit 301 is configured to apply a constant voltage between the CCS block 300 and the spindle part 102 by a power source not shown. The detection device 302 detects changes in whether there is electrical conduction in the detection circuit 301, in other words, contact between the first blade 101A (more precisely, the outer edge of the first blade 101A) and the CCS block 300, and contact between the first blade 101A and the package substrate 4, and notifies the control unit 50 to be described later.

### <2-4. Control Unit>

The control unit 50 is electrically connected to the cutting unit 10, the holding unit 20, and the detecting unit 30, and is configured to control the operation of each of the units 10 to 30. The control unit 50 may be configured integrally with each of the units 10 to 30, or may be configured as a separate body from each of the units 10 to 30. As shown in FIG. 5, the control unit 50 includes a control part 500, a display part 501, an input part 502, and a storage part 503.

The control part 500 includes a CPU (Central Processing Unit), a RAM (Random Access Memory), a ROM (Read Only Memory), etc. An operation program 5000 for controlling the operation of each of the units 10 to 30 is stored in the ROM. The CPU reads and executes the operation program 5000 from the ROM. The ROM is appropriately used for the arithmetic processing of the CPU. The operation program 5000 may be stored in the storage part 503 instead of the ROM.

The display part 501 is configured to display various information to the user, and is configured to display a user interface screen for accepting input of cutting parameters and detection parameters, which will be described later, from the user. The display part 501 can be implemented in any form such as a liquid crystal display element, a liquid crystal display, an organic EL display, and a touch panel display.

The input part 502 inputs, for example, the above-mentioned fixed values or various parameters for cutting. The input part 502 can be implemented in any form such as a keyboard, a push button, and a touch panel display. In a case where the input part 502 is implemented with a touch panel display, the input part 502 may also serve as the display part 501.

The parameters for cutting are not particularly limited, but include, for example, cutting parameters that specify the position where the package substrate 4 is to be cut. Since the package substrate 4 is normally cut according to a grid-shaped cutting pattern, vertical and horizontal cutting lines are determined by determining the cutting parameters.

### <2-5. Calculation of Half Cutting Height>

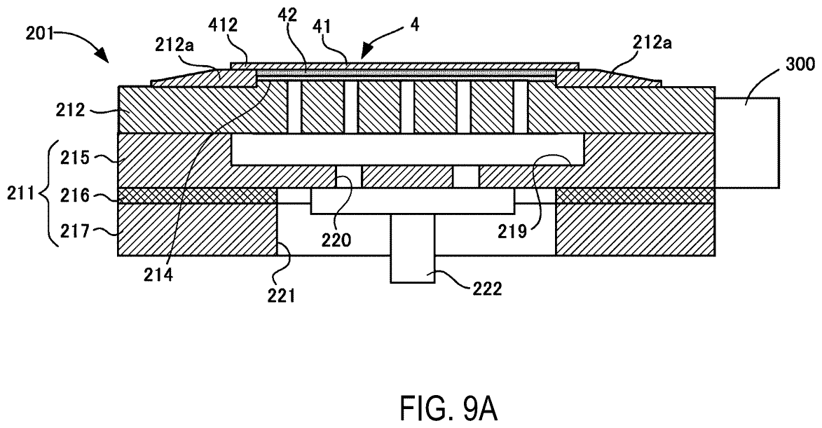

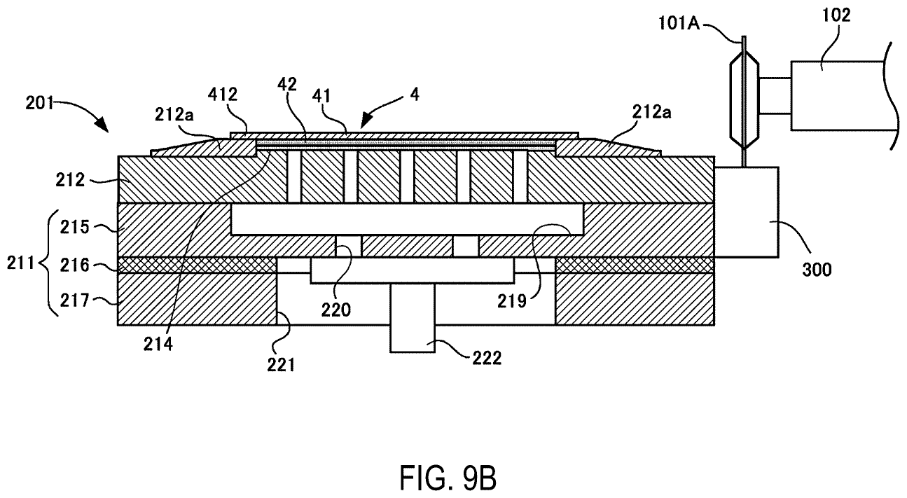

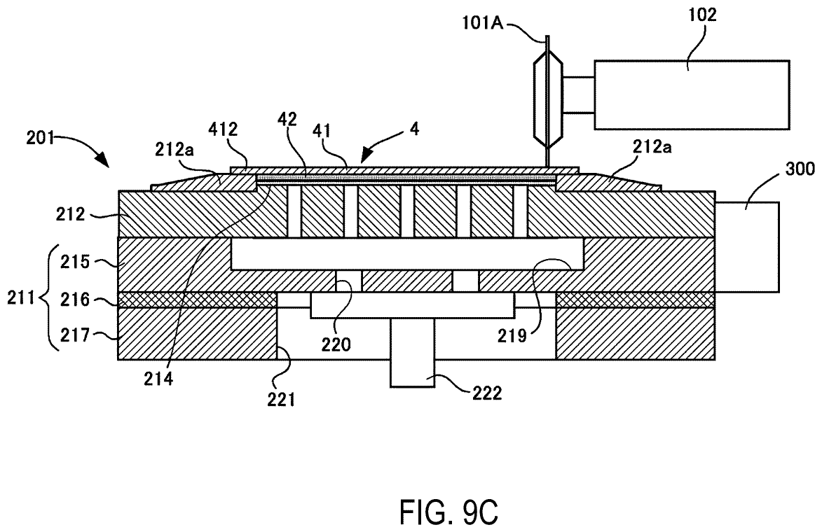

Next, the calculation of the half cutting height performed by the control part 500 will be described. The half cutting height refers to the position of the lowest end of the first blade 101A when performing half cutting on the package substrate 4. The control part 500 controls the position of the spindle part 102 in the height direction and brings the first blade 101A close to the upper surface of the CCS block 300. As shown in FIG. 9B described later, the control part 500 recognizes the coordinate of the spindle part 102 in the height direction when contact between a new unworn first blade 101A and the CCS block 300 is detected as the reference Z-coordinate (hereinafter referred to as the reference coordinate). Thereby, the height position of the spindle part 102, and thus the height position of the first blade 101A, is detected with reference to the upper surface of the CCS block 300. Furthermore, the control part 500 controls the position of the spindle part 102 in the height direction to bring the first blade 101A close to the upper surface of the package substrate 4. The height position of the spindle part 102 controlled by the control part 500 is specifically, for example, the position of the rotation axis of the spindle part 102 in the Z-axis direction, and the control part 500 can determine the position of the spindle part 102 in the Z-axis direction by converting the rotation direction and rotation speed of the motor that moves the spindle part 102 along the ball screw into the moving distance of the Z-axis coordinate.

As an example, the calculation can be performed as follows. First, the coordinate in the height direction (A+B+C-D-E) is calculated by adding the distance from the upper surface of the CCS block 300 to the upper surface of the suction plate 214 (fixed value B) and the thickness of the package substrate 4 (fixed value C) to the reference coordinate (A), and then subtracting the cutting amount of half cutting (fixed value D) and the correction amount caused by the wear of the first blade 101A at the start of half cutting (measured value E). Then, as shown in FIG. 7, the position of the spindle part 102 in the height direction is controlled so that the lowest end portion of the first blade 101A is arranged at the calculated coordinate (hereinafter referred to as the processing base coordinate). The fixed values are input and stored in the cutting apparatus 1 in advance. The correction amount caused by the wear of the first blade 101A at the start of half cutting (measured value) can be calculated from the coordinate in the height direction when the first blade 101A is in contact with the CCS block 300, and the reference coordinate mentioned above (for the wear of the first blade 101A and the correction of the position of the first blade 101A in the height direction caused by the wear, refer to Japanese Patent Application Laid-Open No. 2022-151243).

Furthermore, the position of the spindle part 102 in the height direction is controlled in consideration of the actual thickness of the package substrate 4. That is, as shown in FIG. 9C described later, the first blade 101A is brought into contact with the package substrate 4. From the coordinate in the height direction (F) at this time, the difference between the actual thickness of the package substrate 4 and the thickness of the package substrate 4 (fixed value C) is calculated as the offset amount of the height of the package substrate 4 (A+B+C−F). Then, considering this offset amount, the processing base coordinate is modified, and the position of the spindle part 102 in the height direction is controlled so as to arrange the lowest end portion of the first blade 101A.

Furthermore, the correction due to the wear of the first blade 101A caused by performing half cutting is performed, for example, at a timing when the half cutting length or half cutting time exceeds a set value. That is, when the half cutting length or half cutting time exceeds the set value (may be a timing after the completion of half cutting of one cutting line, or a timing during the half cutting), the first blade 101A is brought into contact with the CCS block 300 to obtain the coordinate in the height direction at that time. Then, from this and the reference coordinate mentioned above, the correction amount caused by the wear of the first blade 101A is calculated (refer to Japanese Patent Application Laid-Open No. 2022-151243), and the position of the spindle part 102 in the height direction is corrected.

### <3. Operation of Cutting Apparatus>

### <3-1. Singulation of Package Substrate>

Next, a method of cutting the package substrate 4 to form the semiconductor package 40 will be described with reference to FIG. 8A and FIG. 8B. First, the first blade 101A having the first thickness is attached to the spindle part 102, and the package substrate 4 is half cut along the cutting line by the first blade 101A to form a groove pattern composed of multiple half cutting grooves G1 and G2 as shown in FIG. 8A. While forming one half cutting groove G1, G2, the cutting work is not stopped, but when the formation of one half cutting groove G1, G2 is completed, for example, the cutting distance which will be described later is determined. The outermost portion of the package substrate 4 cut by the first blade 101A is the boundary line between the use region 411 and the non-use region 412, and the outside of this boundary line (one-dot chain line shown in FIG. 8A) is the non-use region 412 mentioned above, which does not include semiconductor chips, etc. after full cutting, and is a region that does not become the semiconductor package 40. As shown in FIG. 9C described later, this boundary line cut by the first blade 101A is above the resin layer 42 and is within the recess 213 in a plan view.

FIG. 8B is a side schematic view of the vicinity of the half cutting grooves G1 and G2 of the package substrate 4. After forming the groove pattern, the second blade 101B having the second thickness smaller than the first thickness is attached to the spindle part 102, and the package substrate 4 is full cut at a position P1 by the second blade 101B to singulate the package substrate 4. The position P1 is preferably the center of the half cutting grooves G1 and G2. This manufactures multiple semiconductor packages 40 with the step parts 401 formed as shown in FIG. 2. The cross-sectional shapes of the half cutting grooves G1 and G2 are not limited to the shape shown in FIG. 8B.

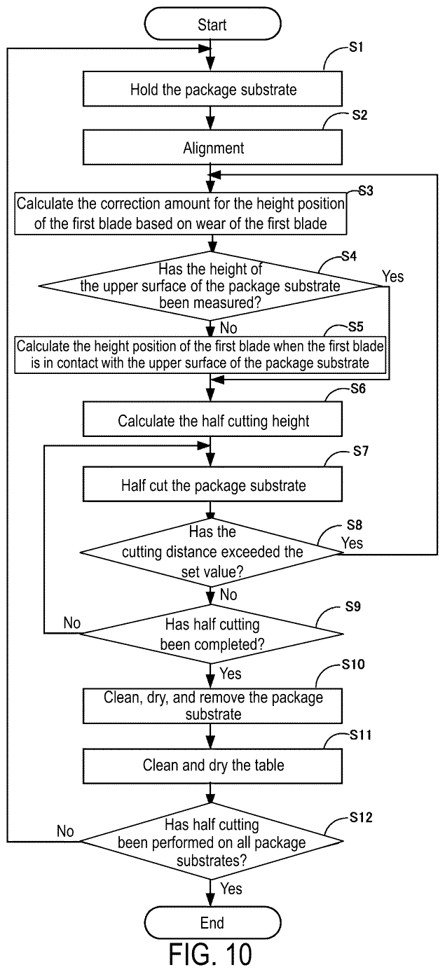

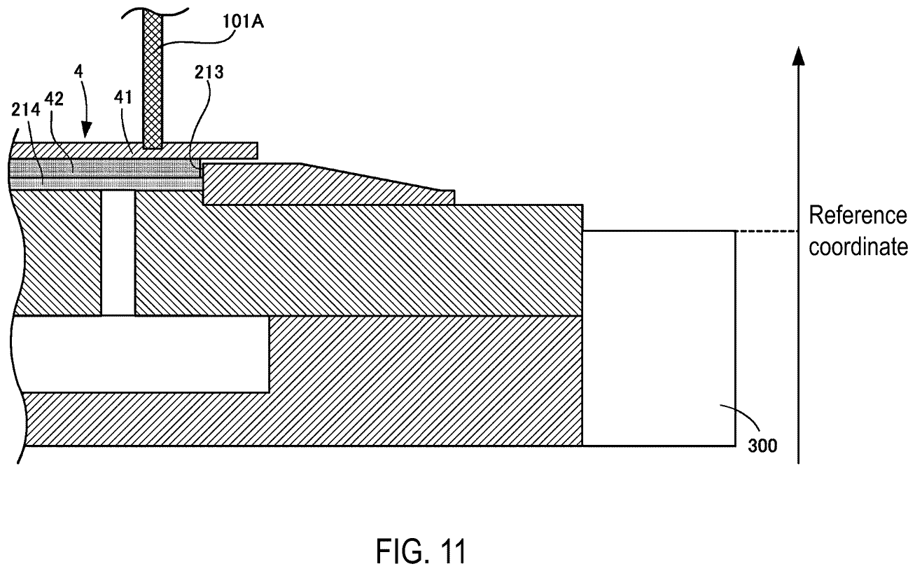

In a case of forming the groove pattern on the package substrate 4 by half cutting, it is important to form the half cutting grooves G1 and G2 with depth as uniform as possible on the package substrate 4, and high accuracy is required. Therefore, in this embodiment, control for half cutting is performed as follows. The half cutting of the package substrate 4 will be described below with reference to the flowchart shown in FIG. 9A to FIG. 9C and FIG. 10.

### <3-2. Half Cutting of Package Substrate>

First, as shown in FIG. 9A, the package substrate 4 is positioned and arranged in the recess 213 of the holding unit 2, and air is sucked through the holes of the suction plate 214 to hold the package substrate 4 on the support part 212 (step S1). As a result, the non-use region 412 of the substrate 41 of the package substrate 4 comes into contact with the upper surface of the support part 212, so the package substrate 4 and the support part 212 are in conduction.

Next, the spindle part 102 and the movement mechanism 203 are operated to perform positioning (alignment) between the first blade 101A and the package substrate 4 (step S2). Then, as shown in FIG. 9B, the spindle part 102 is moved to bring the first blade 101A into contact with the CCS block 300, and the height position of the first blade 101A at this time is stored in the storage part 503. Thus, as described above, the correction amount caused by the wear of the first blade 101A is calculated and stored in the storage part 503 (step S3).

Subsequently, if the height of the upper surface of the package substrate 4 has not been measured (NO in step S4), as shown in FIG. 9C, the spindle part 102 is moved to bring the first blade 101A into contact with a portion that is the non-use region 412 on the second surface of the substrate 41 of the package substrate 4, where the resin layer 42 is formed on the first surface side below. Since the outer peripheral part of the package substrate 4 is in contact with the support part 212, current flows via the first blade 101A and the substrate 41, and electrical conduction is detected by the detection device 302. Thus, the height position of the first blade 101A is calculated (step S5) and stored in the storage part 503. Based on this, the above-mentioned offset amount is calculated and stored in the storage part 503. On the other hand, if the height of the upper surface of the package substrate 4 has been measured (YES in step S4), the half cutting height is calculated as follows.

That is, the half cutting height of the first blade 101A is calculated from the correction amount and offset amount calculated as described above, and the processing base coordinate (step S6). Based on this, the height position of the lowest end portion of the first blade 101A is adjusted to a position that is lowered by the cutting amount of half cutting from the height position where the first blade 101A comes into contact with the package substrate 4.

Thereafter, the spindle part 102 is moved to perform half cutting on the package substrate 4 along the cutting line described above (step S7). At this time, as shown in FIG. 7, the blade edge at the lower end of the first blade 101A is maintained at the half cutting height described above, and half cutting is performed. In this process, when the half cutting on one cutting line is completed, and when the cutting distance of this first blade 101A exceeds a set value (YES in step S8), it is determined that wear has occurred in the first blade 101A, and the above-mentioned correction amount is calculated (step S3). On the other hand, in a case where the cutting distance does not exceed the set value (NO in step S8), it is determined whether half cutting has been performed on all cutting lines in the package substrate (step S9). In step S8, instead of the cutting distance of the first blade 101A, it may be determined whether the cutting time of the first blade 101A exceeds a set value.

In step S9, if half cutting has not been performed on all cutting lines (NO in step S9), half cutting is performed on another cutting line (step S7). If half cutting has been performed on all cutting lines (YES in step S9), the package substrate 4 is cleaned, dried, and then removed from the support part 212 and transported out (step S10). Following this, the table 201 is cleaned and dried (step S11). Thereafter, if half cutting is completed for all package substrates 4 (YES in step S12), the operation of the cutting apparatus 1 is terminated, and if there are remaining package substrates 4 to be half cut (NO in step S12), a new package substrate 4 is held on the support part 212 (step S1), and half cutting is continued.

Next, the cutting apparatus 1 can further perform full cutting. In this case, blade replacement is performed, and the second blade 101B is attached to the spindle part 102 instead of the first blade 101A. Then, full cutting is performed with the second blade 101B after replacement. The second blade 101B cuts and separates the package substrate 4 in the thickness direction according to the formed groove pattern. This results in multiple singulated semiconductor packages 40. After the full cutting is completed, the semiconductor packages 40 may be sent to other units included in the cutting apparatus 1.

### <4. Features>

According to this embodiment, the following effects can be obtained.

(1) In the package substrate 4, which is the target to be cut, the thickness of at least one of the substrate 41 and the resin layer 42 may differ from the design value. Therefore, simply calculating the half cutting height in consideration of the correction amount caused by the wear of the first blade 101A does not result in a constant depth of the half cutting groove, and there is a risk of variations for each package substrate 4. Additionally, variations in the thickness of the suction plate 214 of the table 201 may also cause variations in the height of the package substrate 4, which may also cause the depth of the half cutting groove to be not constant. Particularly, in the semiconductor package 40 as described above, it is desirable that the half cutting groove be formed with high accuracy.

Therefore, in this embodiment, the first blade 101A is brought into contact with the upper surface of the package substrate 4 to directly measure the height position of the package substrate 4, and based on this, the half cutting height of the first blade 101A is calculated. As a result, even if the thickness of the substrate 41 and/or the resin layer 42 differs from the design value, this difference is used as the offset amount mentioned above in the calculation of the half cutting height, so the depths of the half cutting grooves G1 and G2 can be controlled to suppress variations for each package substrate 4. Therefore, highly accurate semiconductor packages 40 can be manufactured.

It is also possible to use an optical sensor, for example, to measure the height position of the package substrate 4. However, due to the surface properties of the package substrate 4 and the cutting environment, light reflection defects may occur, which may prevent accurate measurement of the height position. In contrast, in this embodiment, as described above, the height position can be measured by directly bringing the first blade 101A into contact with the package substrate 4, so the height position can be measured accurately.

(2) When measuring the height position of the package substrate 4, the first blade 101A is brought into contact with the non-use region 412 of the package substrate 4. Therefore, there are no scratches or dents caused by the first blade 101A in the use region 411 that is to be made into a product.

(3) In a case where the thickness of the package substrate 4 to be half cut is not within the allowable range, in the half cutting process, an error occurs and the cutting apparatus 4 stops. As described above, since the correction amount and the offset amount have been stored, by referring to the stored data, it is possible to verify whether the error results from the correction for the wear of the first blade 101A or the thickness of the package substrate 4.

### B. Second Embodiment

Next, the second embodiment of the cutting apparatus according to the present invention will be described. In the following, mainly the portions that differ from the first embodiment will be described, and the description for identical parts will be omitted by assigning the same reference numerals.

### <1. Depth of Arrangement Space>

In the cutting apparatus according to this embodiment, as shown in FIG. 11, the depth of the arrangement space of the recess 213 is set to be smaller than the thickness of the resin layer 42. Therefore, the resin layer 42 can be reliably in contact with the suction plate 214 at the bottom surface of the recess 213 to reliably hold the package substrate 4 on the table 201 by suction. In this embodiment, in a state where the package substrate 4 is only arranged and held on the table 201, the outer peripheral part of the package substrate 4 is not in contact with the support part 212 of the table 201, and there is no conduction between the support part 212 and the package substrate 4.

### <2. Structure of Pressing Mechanism>

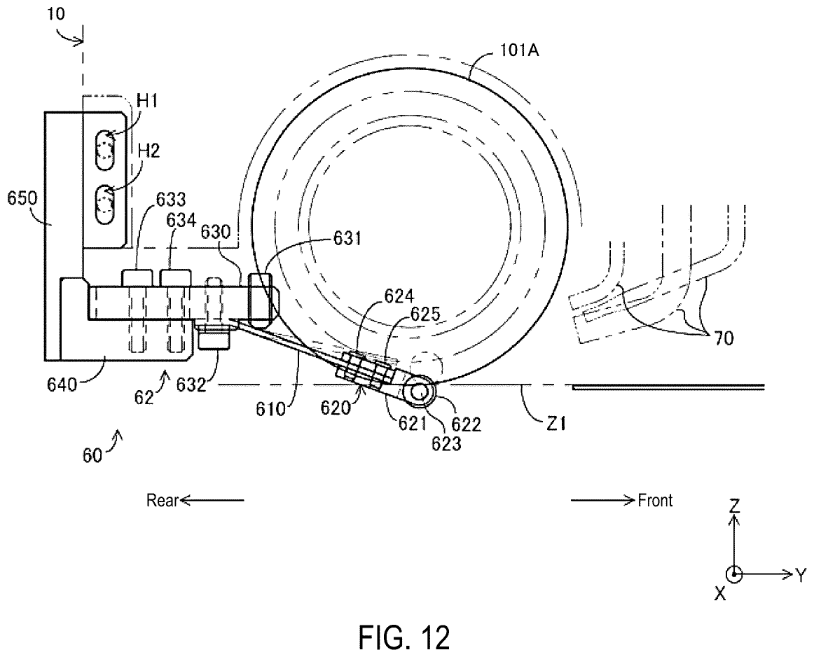

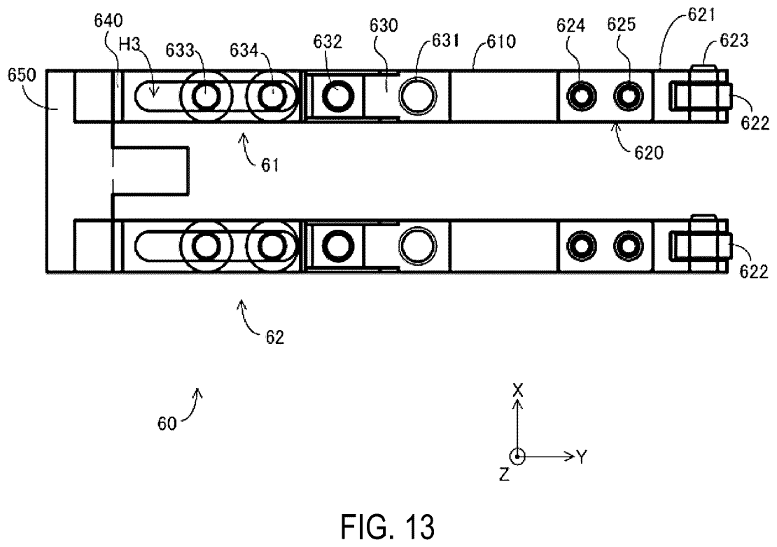

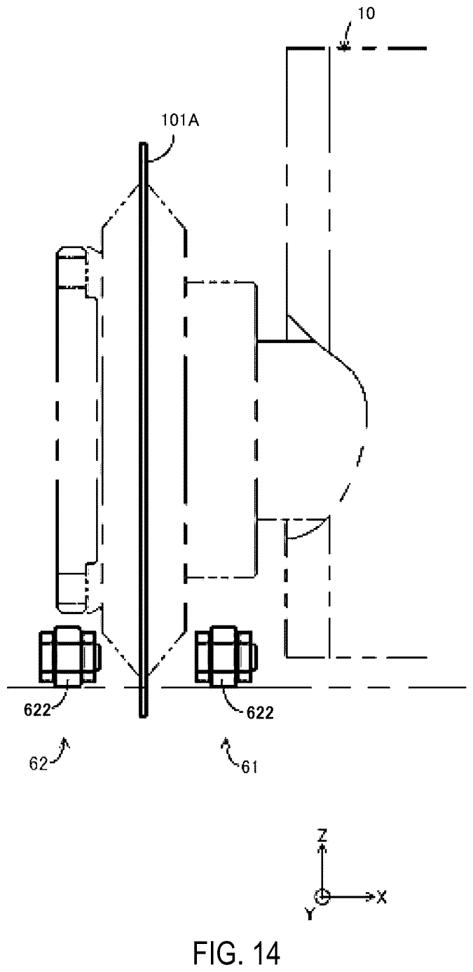

The cutting apparatus according to this embodiment is provided with a pressing mechanism for pressing the package substrate 4 during cutting. The pressing mechanism is an example of the “contact mechanism.” FIG. 12 is a schematic view showing the relationship between the pressing mechanism 60 and the first blade 101A from a side, FIG. 13 is a plan view schematically showing the pressing mechanism 60, and FIG. 14 is a schematic view showing the relationship between the pressing mechanism 60 and the first blade 101A from the front.

As shown in FIG. 12 to FIG. 14, the pressing mechanism 60 is provided in the cutting unit 10. The pressing mechanism 60 includes a first pressing mechanism 61 and a second pressing mechanism 62. The first blade 101A is arranged between the first pressing mechanism 61 and the second pressing mechanism 62, and the first pressing mechanism 61 and the second pressing mechanism 62 are configured to move in conjunction with each other and with the vertical movement of the first blade 101A. The lowest ends of rollers 622 (to be described later) of the first pressing mechanism 61 and the second pressing mechanism 62 are arranged below the lowest end of the first blade 101A (see FIG. 12). Therefore, during cutting of the package substrate 4 performed by the first blade 101A, when the first pressing mechanism 61 and the second pressing mechanism 62 descend together with the descent of the first blade 101A, the first pressing mechanism 61 and the second pressing mechanism 62 come into contact with the package substrate 4 before the first blade 101A, and are configured to press the package substrate 4. That is, during cutting of the package substrate 4 performed by the first blade 101A, in a side view, a portion of the first pressing mechanism 61 faces one side surface of the first blade 101A, and a portion of the second pressing mechanism 62 faces the other side surface of the first blade 101A.

Each of the first pressing mechanism 61 and the second pressing mechanism 62 is configured to press the package substrate 4 downward from above. Therefore, each of the first pressing mechanism 61 and the second pressing mechanism 62 includes a plate spring 610, a pressing unit 620, base members 630 and 640, and screws 624, 625, 631, 633, and 634.

Each of the base members 630, 640, and 650 is made of, for example, metal. The base member 650 is a plate-shaped member extending in the height direction and is attached to the rear end part of the cutting unit 10. Holes H1 and H2 are formed on each of both side surfaces of the base member 650. Each of the holes H1 and H2 is a vertically elongated hole. By passing screws through the holes H1 and H2, the base member 650 is fixed to the cutting unit 10. The position of the pressing mechanism 60 in the height direction can be changed by changing the position in the height direction where the screw is fastened in each of the holes H1 and H2.

The base member 640 is a member extending forward from the lower end part of the base member 650 and is attached to the base member 650. The base member 630 is a rod-shaped member attached to the upper surface of the base member 640 and extends forward from the base member 640. Screw holes are formed in each of the base members 630 and 640, and the base members 630 and 640 are screwed to each other by the screws 633 and 634. A hole H3 formed in each of the base members 630 and 640 has a shape that is long in the front-rear direction, and the position of the roller 622 in the front-rear direction can be adjusted by adjusting the screw fastening position.

The plate spring 610 extending diagonally downward is attached to the lower surface of the base member 630. The plate spring 610 is made of, for example, metal. A screw hole is formed in the plate spring 610, and the base member 630 and the plate spring 610 are screwed to each other by a screw 632. The screw 631 penetrates through the screw hole of the base member 630 and presses the plate spring 610 from above. In the plate spring 610, the position pressed by the screw 631 is in front of the position screwed to the base member 630 by the screw 632. The bending degree of the plate spring 610 is adjusted by adjusting the position of the screw 631 in the height direction. This adjusts the elastic force of the plate spring 610.

The pressing unit 620 is attached to the tip part of the plate spring 610. The pressing unit 620 includes a base member 621, a roller 622, a rotation shaft 623, and screws 624 and 625. The base member 621 is made of, for example, metal or resin. A screw hole is formed in the base member 621, and the base member 621 and the plate spring 610 are screwed to each other by the screws 624 and 625. In a plan view, a recess is formed at the tip part of the base member 621, and the roller 622 is positioned in this recess. The roller 622 is attached to the base member 621 via the rotation shaft 623 and is rotatable with respect to the base member 621. The rotation shaft 623 extends in the X-axis direction (thickness direction of the first blade 101A). The roller 622 is made of, for example, rubber or resin. The roller 622 is an example of the “pressing member” of the present invention. By using the elastic roller 622 made of rubber or resin, it is possible to reduce marks left on the package substrate 4, which are pressed by the roller 622. Also, it is possible to reduce the crushing of burrs generated during half cutting.

In a state where no package substrate 4 exists below the roller 622, the lower end of the roller 622 is positioned below a virtual plane Z1 indicating the lower end position of the first blade 101A. Therefore, during cutting of the package substrate 4, the lower end of the roller 622 comes to a position higher than the lower end of the first blade 101A, so the roller 622 presses down the package substrate 4 with the elastic force of the plate spring 610.

### <3. Features>

According to this embodiment, the following effects can be obtained.

(1) With the roller 622 pressing down the package substrate 4, half cutting is performed on the package substrate 4 in a state where warping of the package substrate 4 is suppressed. Therefore, variations in the depth of the groove formed by half cutting can be suppressed.

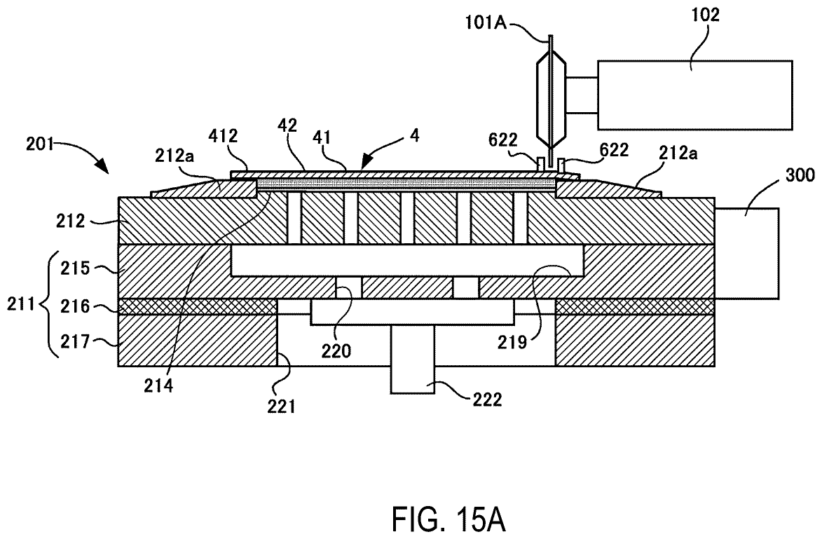

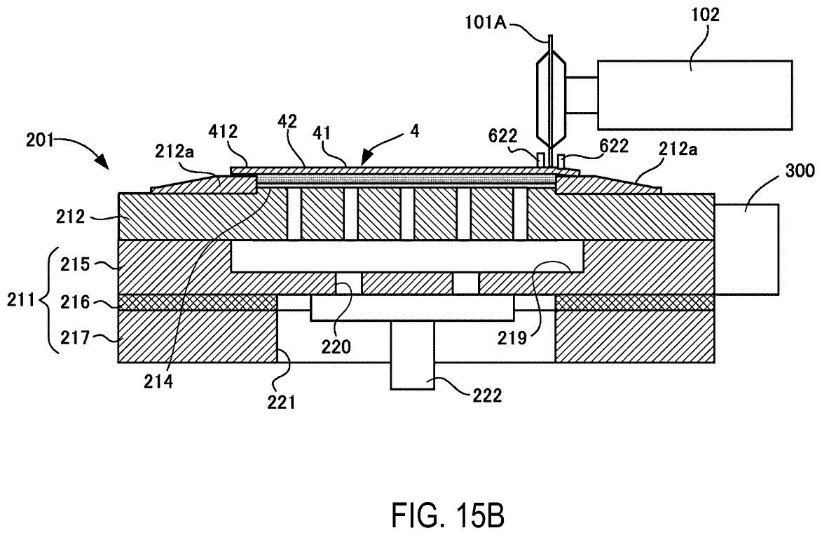

(2) As shown in FIG. 15A, when measuring the Z-coordinate of the upper surface of the package substrate 4, the roller 622 descends together with the descent of the first blade 101A, and first, the non-use region 412 of the package substrate 4 can be pressed by the roller 622. As a result, the substrate 41 of the package substrate 4 and the support part 212 are in contact, and the support part 212 and the package substrate 4 are in conduction. Subsequently, as shown in FIG. 15B, when the first blade 101A comes into contact with the substrate 41 of the package substrate 4, current flows via the first blade 101A and the substrate 41, and electrical conduction can be detected by the detection device 302.

Additionally, even if the depth of the arrangement space of the recess 213 and the thickness of the resin layer 42 are the same, for example, in a case where warping occurs in the package substrate 4, the outer peripheral part of the package substrate 4 may separate from the upper surface of the support part 212, and there may be no conduction or no sufficient conduction between the package substrate 4 and the support part 212. In contrast, by pressing the non-use region 412 of the package substrate 4 with the roller 622, as shown in FIG. 15A, the non-use region 412 of the package substrate 4 can be brought into contact with the upper surface of the support part 212. Therefore, the conduction between the package substrate 4 and the support part 212 can be reliably secured, making it possible to accurately measure the position of the upper surface of the package substrate 4.

In order to achieve conduction between the non-use region 412 and the upper surface of the support part 212 in this way, one roller 622 is arranged outside the recess 213.

### C. Modification Example

While an embodiment of the present invention has been described above, the present invention is not limited to the above embodiments, and various modifications are possible as long as they do not deviate from the spirit of the present invention. For example, the following modifications are possible. In addition, the gist of the following modification examples can be combined as appropriate.

### <C-1>

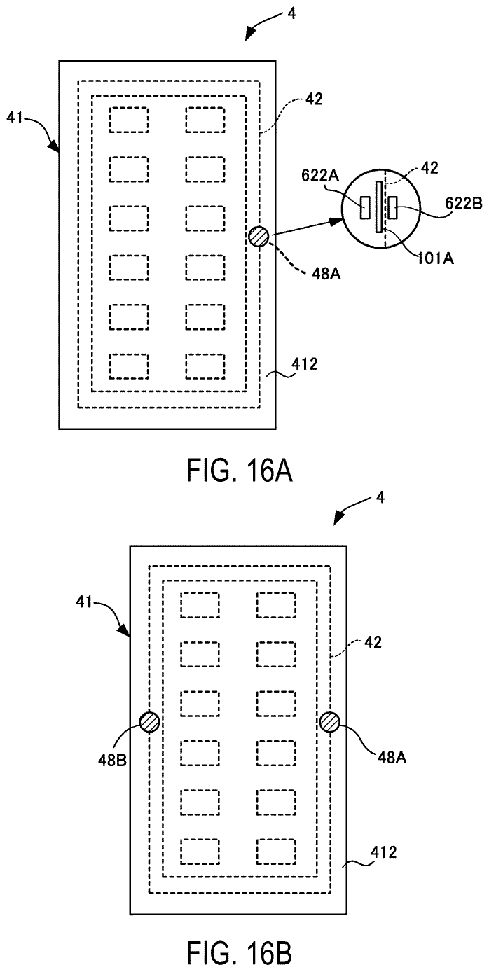

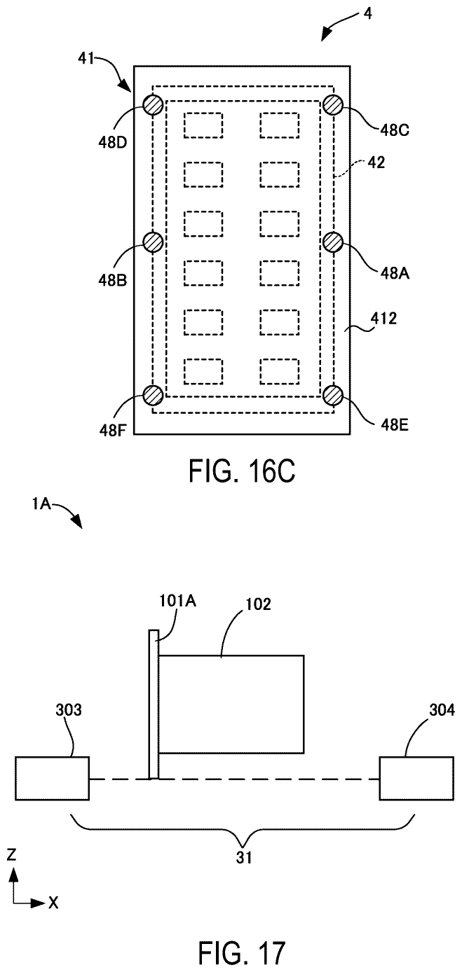

In a case of measuring the height position of the upper surface in the package substrate, the number and positions of measurement locations are not particularly limited, and there may be one or more measurement locations. For example, as shown in FIG. 16A, there can be one measurement location 48A. At the measurement location 48A, as shown in the enlarged view of FIG. 16A, the first blade 101A is arranged between a pair of rollers 622A and 622B. Among the pair of rollers 622A and 622B, one roller 622A is arranged inside the resin layer 42, and the other roller 622B is arranged outside the resin layer 42 (outside the recess 213). This point also applies to FIG. 16B and FIG. 16C which will be described next. In the cutting apparatus 1 of the first embodiment, only the first blade 101A is arranged.

In addition, the height position of the upper surface can be measured at multiple measurement locations. For example, in the example of FIG. 16B, measurement locations 48A and 48B can be provided on both sides in the lateral direction in the non-use region 412 of the package substrate 4. Alternatively, as shown in FIG. 16C, in addition to the measurement locations 48A and 48B of FIG. 16B, measurement locations 48C to 48F can be provided at four locations near the corners of the package substrate 4 in the non-use region 412 of the package substrate 4.

In a case of measuring the height position of the upper surface at multiple measurement locations, for example, the average of multiple height positions measured can be used as the height position. In addition, in a case where the measured height position of the upper surface is larger than a predetermined value due to warping, that package substrate 4 can also be collected without performing half cutting. In a case of performing measurement at multiple locations, for example, in a case where the upper surface height position at one location exceeds a predetermined value, that package substrate 4 can also be collected without performing half cutting.

### <C-2>

The measurement frequency of the height position of the package substrate 4 is not particularly limited, and the measurement may be performed for each package substrate 4 as in the above embodiments, or for example, the thickness and warping of each package substrate 4 may be measured separately for each lot, and if these are within acceptable values, the height position measurement can also be performed for each lot.

### <C-3>

The configuration of the detecting unit 30 is not limited to the configuration of the above embodiments, and can be appropriately changed. For example, the table 201 itself may be configured as a contact element. Also, the position where the CCS block 300 serving as a contact element is arranged is not limited to the above embodiments, and may be separated from the table 201, for example, and can be appropriately changed. Additionally, the number of CCS blocks 300 included in the cutting apparatus is not particularly limited. The configuration of the detection circuit 301 may also be appropriately changed.

### <C-4>

The pressing mechanism 60 is not necessarily required and may be appropriately provided as needed.

### <C-5>

The cutting apparatus 1 according to the first embodiment and the second embodiment includes the detecting unit 30 including the CCS block 300, the detection circuit 301, and the detection device 302 as the detecting part for detecting wear of the first blade 101A. However, as shown in FIG. 17, it is also possible to include a detecting unit 31 including a light emitting part 303 and a light receiving part 304 as the detecting part for detecting wear of the first blade 101A. That is, in the above embodiments, the wear of the first blade 101A is detected in a contact manner using a contact element in the cutting apparatus 1, but in a cutting apparatus 1A in this example, the wear of the first blade 101A is detected in a non-contact manner without bringing the first blade 101A into contact with a contact element.

The light emitting part 303 includes a light emitting element. Examples of the light emitting element include a light projecting side fiber of a fiber sensor, an LED, etc. The light emitting element is arranged to face a light receiving element of the light receiving part 304 to be described later, and emits a light beam substantially parallel to the X-axis.

On the other hand, the light receiving part 304 includes a light receiving element. Examples of the light receiving element include a light receiving side fiber of a fiber sensor, a light receiving element that receives light emitted by an LED, etc. The light receiving element is arranged to face the light emitting element of the light emitting part 303, and to have a position in the Z-axis direction that matches the light emitting element. In a state where there is no object blocking between the light emitting element and the light receiving element, the light beam emitted from the light emitting element reaches the light receiving element. The light receiving element is configured to convert a change in the light beam reaching the light receiving element into an electrical signal.

When an object exists between the light emitting element and the light receiving element, the light beam emitted from the light emitting element is blocked by the object, and does not reach or hardly reaches the light receiving element. Thus, the electrical signal emitted by the light receiving element changes, and it is detected that an object exists at the position of the light beam in the Z-axis direction. When the object is the first blade 101A, the detecting unit 31 detects that the edge end of the first blade 101A exists at the position of the light beam in the Z-axis direction by detecting the intensity of the light beam reaching the light receiving part 304. The control unit 50 is notified of the detection state of the change in light beam detected by the detecting unit 31. The control unit 50, similar to the first embodiment, gradually moves the spindle part 102 toward the light beam between the light emitting part 303 and the light receiving part 304, with a coordinate in the height direction as the starting point. The control part 500 recognizes the coordinate of the spindle part 102 in the height direction when the blocking of the light beam caused by the first blade 101A is detected, as the end point, based on a notification from the detecting unit 31. This allows detection of the height of the spindle part 102, and thus the first blade 101A, at the starting point.

### <C-6>

The operations of the cutting unit 10 and the holding unit 20 are not limited to the exemplary operations in the above embodiments. For example, when performing cutting, the blades 101A and 101B may be fixed and the table 201 may be moved. That is, cutting may be performed while the blades 101A and 101B move relative to the table 201. In addition, for example, the possible operation of the table 201 may be limited to only rotational movement, and cutting of the package substrate 4 may be performed by moving the spindle part 102 in the Y-axis direction. That is, cutting of the package substrate 4 may be performed by relatively moving the table 201 and the blade 101. For example, the CCS block 300 or the package substrate 4 may be brought into contact with the blade 101, or the package substrate 4 may be cut by raising the table 201.

### <C-7>

The pressing mechanism 60 of the second embodiment described above is an example of the contact mechanism for bringing the outer peripheral part of the package substrate 4 into contact with the frame part 212a, and other configurations may be adopted as long as it is possible to press the outer peripheral part of the package substrate 4 and bring the outer peripheral part into contact with the frame part 212a to establish conduction when there is a gap between the outer peripheral part of the package substrate 4 and the frame part 212a.

Furthermore, the contact mechanism may have a configuration other than pressing the outer peripheral part. For example, a conductive spring plunger may be provided to protrude from the portion of the support part 212 where the package substrate 4 is mounted (the portion facing the outer peripheral part). Since the resin layer 42 of the package substrate 4 is held in the recess 213 by suction, even if the outer peripheral part of the package substrate 4 is warped, the outer peripheral part of the package substrate 4 can be in contact with the protruding conductive spring plunger to maintain a conductive state.

### <C-8>

In the first embodiment described above, the pressing mechanism of the above second embodiment or the spring plunger described in <C-7> may be included. As described above, even if the depth of the arrangement space of the recess 213 and the thickness of the resin layer 42 are the same, in a case where warping occurs in the package substrate 4, electrical conduction between the package substrate 4 and the first blade 101A can be ensured, and furthermore, the Z-coordinate of the upper surface of the package substrate 4 can be accurately measured.

### <C-9>

In the embodiments described above, the correction amount caused by the wear of the first blade 101A is calculated, and the half cutting height is calculated in consideration of this, but the timing for calculating the correction amount is not limited to that shown in the above embodiments and can be determined as appropriate. In addition, whether to calculate the correction amount caused by the wear may be determined based on the time during which half cutting is performed rather than the cutting distance over which half cutting is performed. Furthermore, the half cutting height can also be calculated without calculating the correction amount caused by the wear.

The method for calculating the half cutting height shown in the above embodiments is an example, and it is also possible to adjust the height of the spindle part 102 by other methods. For example, the height position of the spindle part 102 during half cutting can be adjusted by lowering the spindle part 102 from the height position of the spindle part 102 when the first blade 101A comes into contact with the package substrate 4 by the cutting amount. Half cutting is performed on the package substrate 4 at this adjusted half cutting height. Then, for example, when the cutting distance of the first blade 101A exceeds a set value, as described above, the correction amount caused by the wear of the first blade 101A is calculated, and the height position of the spindle part 102 may be further lowered by this correction amount to adjust the half cutting height.

### <C-10>

In each embodiment described above, when the first blade 101A is brought into contact with the package substrate 4, conduction therebetween is established, which allows the height position of the first blade 101A to be detected, and based on this, the position of the first blade 101A in the height direction during half cutting is controlled. However, the location where conduction is established is not particularly limited. That is, when the blade 101A is brought into contact with the upper surface of the package substrate 4, conduction may be established at any point for the height position of the blade 101A to be detected.

Furthermore, as long as the height position of the first blade 101A can be detected, methods other than conduction may be used when the first blade 101A comes into contact with the package substrate 4. For example, various sensors may be used to detect the contact between the first blade 101A and the package substrate 4, and it suffices if the height position of the first blade 101A at that time can be obtained.

### <C-11>

In the above embodiments, the object to be cut is exemplified as the package substrate 4, and the cut product is exemplified as the semiconductor package 40. However, examples of the object to be cut and the cut product are not limited to these. The present invention can also be applied in cases where half cutting is performed on other objects to be cut.

### <C-12>

In the above embodiments, after the completion of half cutting, the first blade 101A is replaced with the second blade 101B. However, in a case where the cutting apparatus 1 includes two or more spindle parts 102, the second blade 101B may be attached to another spindle part 102 in advance, and full cutting may be performed without replacing the blade 101. In addition, processing other than cutting, such as plating treatment, may be performed on the package substrate 4 at a timing after the completion of half cutting and before the start of full cutting.

### <C-13>

The support part 212 in the above embodiments can also be configured to be detachable from the first portion 215 of the base 211 (see FIG. 6). For example, the support part 212 can be formed for each type of package substrate 4 to be cut (for example, the shape, depth, etc. of the recess), and can be fixed to the first portion 215 in an exchangeable manner. Also, the configuration of the portion supporting the package substrate 4 in the table 201 is not particularly limited as long as the configuration supports the package substrate 4 so that the package substrate 4 does not move during cutting and has a portion for conduction with the conduction region (for example, the outer peripheral part).

### <C-14>

The cutting apparatus 1 may be configured as a dedicated half cutting apparatus that performs only half cutting. In this case, the blade replacement of the cutting apparatus 1 can be omitted. Then, the full cutting using the second blade 101B may be performed using a separate device.

Several embodiments of the present invention have been described above as examples. That is, detailed description and accompanying figures have been disclosed for illustrative purposes. Therefore, among the components described in the detailed description and accompanying figures, there may be components that are not essential for solving the problem. Accordingly, just because non-essential components are described in the detailed description and accompanying figures, they should not be immediately recognized as essential.

### (Appendix)

In relation to the embodiments described above, the following appendix is further disclosed.

Appendix 1. A cutting apparatus, including:
a table holding an object to be cut;
a cutting mechanism having a blade capable of cutting the object to be cut;
a detecting part detecting contact between the blade and an upper surface of the object to be cut; and
a control part controlling the cutting mechanism,
wherein the control part controls a position of the blade in a height direction during cutting of the object to be cut based on a height position of the blade when the detecting part detects contact between the blade and the upper surface of the object to be cut.

Appendix 2. The cutting apparatus according to Appendix 1,
wherein the blade has conductivity,
the object to be cut includes a conduction region with which the blade comes into contact, and
the detecting part detects that the blade has come into contact with the upper surface of the object to be cut by electrical conduction between the blade and the object to be cut.

Appendix 3. The cutting apparatus according to Appendix 2,
wherein the table includes a conduction part with at least a part capable of facing the conduction region of the object to be cut, and
the detecting part detects that the blade has come into contact with the upper surface of the object to be cut by electrical conduction between the blade, the conduction region of the object to be cut, and the conduction part of the table.

Appendix 4. The cutting apparatus according to Appendix 3, further including a contact mechanism capable of moving the conduction region of the object to be cut and the conduction part of the table holding the object to be cut in a direction to be relatively close to each other, and bringing the conduction region and the conduction part into contact.

Appendix 5. The cutting apparatus according to Appendix 3 or 4,
wherein the object to be cut includes a substrate having the conduction region, and a resin layer formed on a part of one surface of the substrate,
the table has a recess in which the resin layer is arranged, and
an upper surface of the conduction part is at least positioned outside the recess in a plan view, and positioned above a bottom surface of the recess.

Appendix 6. The cutting apparatus according to any one of Appendixes 2 to 5,
wherein the object to be cut has a non-use region that is not made into a product,
the non-use region is included in the conduction region, and
the detecting part detects contact between the blade and the non-use region.

Appendix 7. The cutting apparatus according to any one of Appendixes 1 to 6,
wherein the detecting part detects contact with the blade at a plurality of locations on the upper surface of the object to be cut, and
the control part controls the position of the blade in the height direction during cutting of the object to be cut based on a plurality of height positions of the upper surface determined from the height position of the blade when the detecting part detects contact between the blade and the upper surface of the object to be cut.

Appendix 8. The cutting apparatus according to Appendix 7,
wherein the contact mechanism includes a first pressing member and a second pressing member arranged to sandwich the blade, and
each of the first pressing member and the second pressing member is configured to press the object to be cut downward from above.

Appendix 9. The cutting apparatus according to Appendix 8,
wherein when the blade is brought into contact with the upper surface of the object to be cut, each of the first pressing member and the second pressing member is configured to press the object to be cut downward from above.

Appendix 10. The cutting apparatus according to any one of Appendixes 1 to 9,
wherein the detecting part further detects a position of an outer edge of the blade, and
the control part
calculates a wear amount of the blade from the position of the outer edge of the blade detected by the detecting part, and
controls the position of the blade in the height direction during cutting of the object to be cut based on the wear amount.

Appendix 11. The cutting apparatus according to Appendix 10,
wherein the detecting part includes a contact element having conductivity, and a detection circuit configured to conduct electricity when the blade is brought into contact with the contact element, and
the control part calculates the wear amount of the blade based on the height position of the blade when the detecting part detects electrical conduction of the detection circuit.

Appendix 12. A cutting method, including:
a step of holding an object to be cut on a table;
a step of detecting a height position of an upper surface of the object to be cut by bringing a blade capable of cutting the object to be cut into contact with the upper surface of the object to be cut; and
a step of controlling a position of the blade in a height direction during cutting of the object to be cut based on the height position of the upper surface detected.

Appendix 13. The cutting method according to Appendix 12,
wherein the object to be cut has a non-use region that is not made into a product, and
in the step of detecting the height position of the upper surface of the object to be cut, the blade is brought into contact with an upper surface of the non-use region of the object to be cut.

Appendix 14. A method for manufacturing a cut product, including:
a step of performing half cutting on the object to be cut by the cutting method according to Appendix 12 or 13; and
a step of separating the object to be cut by performing full cutting on a half cutting groove formed by the half cutting.

### DESCRIPTION OF REFERENCE NUMERALS

1 Cutting apparatus
1A Cutting apparatus
4 Package substrate
10 Cutting unit
20 Holding unit
30 Detecting unit
40 Semiconductor package
50 Control unit
101 Blade
5 101A First blade
102B Second blade
201 Table
300 CCS block
301 Detection device
10 302 Detection circuit
500 Control part
G1, G2 Half cutting groove

1. A cutting apparatus, comprising:
a table holding an object to be cut;
a cutting mechanism having a blade capable of cutting the object to be cut;
a detecting part detecting contact between the blade and an upper surface of the object to be cut; and
a control part controlling the cutting mechanism,
wherein the control part controls a position of the blade in a height direction during cutting of the object to be cut based on a height position of the blade when the detecting part detects contact between the blade and the upper surface of the object to be cut.

2. The cutting apparatus according to claim 1,
wherein the blade has conductivity,
the object to be cut comprises a conduction region with which the blade comes into contact, and
the detecting part detects that the blade has come into contact with the upper surface of the object to be cut by electrical conduction between the blade and the object to be cut.

3. The cutting apparatus according to claim 2,
wherein the table comprises a conduction part with at least a part capable of facing the conduction region of the object to be cut, and
the detecting part detects that the blade has come into contact with the upper surface of the object to be cut by electrical conduction between the blade, the conduction region of the object to be cut, and the conduction part of the table.

4. The cutting apparatus according to claim 3, further comprising a contact mechanism capable of moving the conduction region of the object to be cut and the conduction part of the table holding the object to be cut in a direction to be relatively close to each other, and bringing the conduction region and the conduction part into contact.

5. The cutting apparatus according to claim 3,
wherein the object to be cut comprises a substrate having the conduction region, and a resin layer formed on a part of one surface of the substrate,
the table has a recess in which the resin layer is arranged, and
an upper surface of the conduction part is at least positioned outside the recess in a plan view, and positioned above a bottom surface of the recess.

6. The cutting apparatus according to claim 2,
wherein the object to be cut has a non-use region that is not made into a product,
the non-use region is included in the conduction region, and
the detecting part detects contact between the blade and the non-use region.

7. The cutting apparatus according to claim 1,
wherein the detecting part detects contact with the blade at a plurality of locations on the upper surface of the object to be cut, and
the control part controls the position of the blade in the height direction during cutting of the object to be cut based on a plurality of height positions of the upper surface determined from the height position of the blade when the detecting part detects contact between the blade and the upper surface of the object to be cut.

8. The cutting apparatus according to claim 4,
wherein the contact mechanism comprises a first pressing member and a second pressing member arranged to sandwich the blade, and
each of the first pressing member and the second pressing member is configured to press the object to be cut downward from above.

9. The cutting apparatus according to claim 8,
wherein when the blade is brought into contact with the upper surface of the object to be cut, the first pressing member and the second pressing member are configured to come into contact with the object to be cut before the blade, and press the object to be cut.

10. The cutting apparatus according to claim 1,
wherein the detecting part further detects a position of an outer edge of the blade, and
the control part
calculates a wear amount of the blade from the position of the outer edge of the blade detected by the detecting part, and
controls the position of the blade in the height direction during cutting of the object to be cut based on the wear amount.

11. The cutting apparatus according to claim 10,
wherein the detecting part comprises a contact element having conductivity, and a detection circuit configured to conduct electricity when the blade is brought into contact with the contact element, and
the control part calculates the wear amount of the blade based on the height position of the blade when the detecting part detects electrical conduction of the detection circuit.

12. A cutting method, comprising:
holding an object to be cut on a table;
detecting a height position of a blade by bringing the blade capable of cutting the object to be cut into contact with an upper surface of the object to be cut; and
controlling a position of the blade in a height direction during cutting of the object to be cut based on the height position of the blade detected.

13. The cutting method according to claim 12,
wherein the object to be cut has a non-use region that is not made into a product, and
in detecting a height position of an upper surface of the object to be cut, the blade is brought into contact with an upper surface of the non-use region of the object to be cut.

14. A method for manufacturing a cut product, comprising:
performing half cutting on the object to be cut by the cutting method according to claim 12; and
separating the object to be cut by performing full cutting on a half cutting groove formed by the half cutting.
